(19) United States
(12) Patent Application Publication
(10) Pub. No.: US 2026/0053058 A1
(43) Pub. Date: Feb. 19, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Inhee Yoo, Suwon-si (KR)

(21) Appl. No.: 19/206,353

(22) Filed: May 13, 2025

(30) Foreign Application Priority Data
Aug. 16, 2024 (KR) 10-2024-0109653

(51) Int. Cl. H01L 23/24; H01L 23/00; H01L 23/31; H01L 25/00; H01L 25/18; H10B 80/00; H10D 80/30

(52) U.S. Cl. CPC H01L 23/24; H01L 24/32; H01L 25/18; H01L 23/3128; H01L 24/48; H01L 24/49; H01L 24/73; H01L 25/50; H01L 2224/32145; H01L 2224/32225; H01L 2224/48147; H01L 2224/48227; H01L 2224/49175; H01L 2224/73215; H01L 2224/73265; H01L 2225/06506; H01L 2225/0651; H01L 2225/06524; H01L 2225/06562; H01L 2924/1431; H01L 2924/35121; H10B 80/00; H10D 80/30

(57) ABSTRACT

A semiconductor package includes a package substrate, a first semiconductor chip on an upper surface of the package substrate, a spacer chip on the upper surface of the package substrate and spaced apart from the first semiconductor chip, a plurality of second semiconductor chips sequentially stacked on the spacer chip by a plurality of adhesive films, respectively, and a molding member on the spacer chip, the first semiconductor chip, and the plurality of second semiconductor chips. When viewed in a plan view, the spacer chip has an overlapping region overlapping with a lowermost second semiconductor chip of the plurality of second semiconductor chips. The lowermost second semiconductor chip is attached to the spacer chip by a first adhesive film. A portion of the first adhesive film attached to the spacer chip is within a recess that is in an upper surface of the overlapping region of the spacer chip.

### CROSS-REFERENCE TO RELATED APPLICATION

This application claims priority under 35 U.S.C. § 119 to Korean Patent Application No. 10-2024-0109653, filed on Aug. 16, 2024, in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of different chips stacked on a package substrate and a manufacturing method thereof.

### 2. Description of the Related Art

In a multi-chip package (MCP), a spacer chip may be used to support at least a portion of an overlying semiconductor chip. The overlying semiconductor chip may be attached to the spacer chip using an adhesive film such as a die attach film (DAF) by a die attach process. However, in a structure where a portion of the spacer chip is exposed from the overlying semiconductor chip, a triple point where three different materials meet may occur at a lower edge of the adhesive film attached to the spacer chip, and there is a problem in that stress increases due to a difference in coefficients of thermal expansion at the triple point, resulting in a defect in which the adhesive film is peeled off.

### SUMMARY

Example embodiments provide a semiconductor package having improved reliability and a structure capable of preventing interfacial delamination of an adhesive film.

Example embodiments provide a method of manufacturing the semiconductor package.

According to example embodiments, a semiconductor package includes a package substrate, a first semiconductor chip on an upper surface of the package substrate, a spacer chip on the upper surface of the package substrate, the spacer chip being spaced apart from the first semiconductor chip, a plurality of second semiconductor chips sequentially stacked on the spacer chip by a plurality of adhesive films, respectively, to cover the first semiconductor chip, and a molding member on the package substrate and on the spacer chip, the first semiconductor chip, and the plurality of second semiconductor chips. When viewed in a plan view, the spacer chip has an overlapping region overlapping with a lowermost second semiconductor chip of the plurality of second semiconductor chips and an overhang region extending from one side of the lowermost second semiconductor chip. A recess having a predetermined depth is in an upper surface of the overlapping region of the spacer chip. The lowermost second semiconductor chip is attached to the spacer chip by a first adhesive film of the plurality of adhesive films. A portion of the first adhesive film attached to the spacer chip is within the recess of the spacer chip.

According to example embodiments, a semiconductor package includes a package substrate, a first semiconductor chip on an upper surface of the package substrate, a spacer chip on the upper surface of the package substrate, the spacer chip being spaced apart from the first semiconductor chip in a first direction, a plurality of second semiconductor chips sequentially stacked on the spacer chip by a plurality of adhesive films, respectively, to cover the first semiconductor chip, and a molding member on the package substrate and on the spacer chip, the first semiconductor chip and the plurality of second semiconductor chips. The spacer chip has an overhang region extending from one side of a lowermost second semiconductor chip of the plurality of second semiconductor chips. A dam structure having a predetermined height is on an upper surface of the overhang region of the spacer chip. The lowermost second semiconductor chip is attached to the spacer chip by a first adhesive film of the plurality of adhesive films. A lower edge portion of the first adhesive film attached to the spacer chip is covered by the dam structure.

According to example embodiments, a semiconductor package includes a package substrate extending in a first direction, and having a plurality of substrate pads on an upper surface thereof; a first semiconductor chip on the upper surface of the package substrate; first and second spacer chips on the upper surface of the package substrate, the first and second spacer chips being spaced apart from each other in the first direction with the first semiconductor chip between the first and second spacer chips; third and fourth spacer chips attached to the upper surface of the package substrate, the third and fourth spacer chips being spaced apart from each other in a second direction perpendicular to the first direction with the first semiconductor chip interposed between the third and fourth spacer chips; a plurality of second semiconductor chips sequentially stacked on the first, second, third and fourth spacer chips by a plurality of adhesive films, respectively, to cover the first semiconductor chip; conductive connecting members electrically connecting chip pads of the plurality of second semiconductor chips to the substrate pads, respectively; and a molding member on the package substrate on the first, second, third and fourth spacer chips, the first semiconductor chip, and the plurality of second semiconductor chips. When viewed in a plan view, the fourth spacer chip has an overlapping region overlapping with a lowermost second semiconductor chip of the plurality of second semiconductor chips and an overhang region extending from one side of the lowermost second semiconductor chip. A recess having a predetermined depth is in an upper surface of the overlapping region of the fourth spacer chip. The lowermost second semiconductor chip is attached to the fourth spacer chip by a first adhesive film of the plurality of adhesive films. A portion of the first adhesive film attached to the fourth spacer chip is within the recess of the fourth spacer chip.

According to example embodiments, a semiconductor package may include a spacer chip that is spaced apart from a first semiconductor chip on a package substrate, a plurality of second semiconductor chips attached to the spacer chip by a plurality of adhesive films, respectively, to cover the semiconductor chip, and a molding member covering the spacer chip and the second semiconductor chips on the package substrate.

At least a portion of the spacer chip, that is, an overhang region may be arranged to protrude or extend away from one side of a lowermost second semiconductor chip, and a recess may be in an upper surface of an overlapping region of the spacer chip that overlaps with the lowermost second semiconductor chip.

A portion of the adhesive film attached to the spacer chip may be in the recess of the spacer chip. A lower edge portion of the adhesive film attached to the spacer chip may be covered by a dam structure. A central side portion of the adhesive film attached to the spacer chip may be in contact with the molding member. Accordingly, a triple point where three different materials (spacer chip, adhesive film, and molding member) meet moves to the central side portion of the adhesive film, to thereby reduce or prevent the occurrence of interface peeling of the adhesive film in the overhang region of the spacer chip.

Further, an area of a side surface of the adhesive film attached to the spacer chip that is in contact with the molding member may be reduced by the dam structure. Accordingly, in a high-humidity test process, the reliability of the adhesive film having a relatively large moisture absorption expansion amount compared to EMC may be improved.

### BRIEF DESCRIPTION OF THE DRAWINGS

Example embodiments will be more clearly understood from the following detailed description taken in conjunction with the accompanying drawings. FIGS. 1 to 20 represent non-limiting, example embodiments as described herein.

FIG. 1 is a plan view illustrating a semiconductor package in accordance with example embodiments.

FIG. 2 is a cross-sectional view taken along the line A1-A1′ in FIG. 1.

FIG. 3 is a cross-sectional view taken along the line B1-B1′ in FIG. 1.

FIG. 4 is an enlarged cross-sectional view illustrating portion ‘C’ in FIG. 3.

FIGS. 5 to 20 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

Further, spatially relative terms, such as “under,” “below,” “lower,” “over,” “upper”, etc., may be used herein for ease of description to describe one element or relationship of structures to another element or structure as illustrated in the drawings.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

The term “exposed” may be used to describe relationships between elements and/or certain intermediate processes in fabricating a completed semiconductor device but may not necessarily require exposure of the particular region, layer, structure or other element in the context of the completed device. An “element A is exposed through an element B” means that at least a portion of the element A is not covered by the element B. However, the thus exposed portion of the element A may be covered by a third element.

Elements or components described with reference to having “overlap” with each other in at least one particular direction may be at least partially obstructed by one another when viewed along a line extending in the particular direction or in a plane perpendicular to the particular direction. The “overlap” may be direct with components directly on other components or there may be intervening layers or components between the layers.

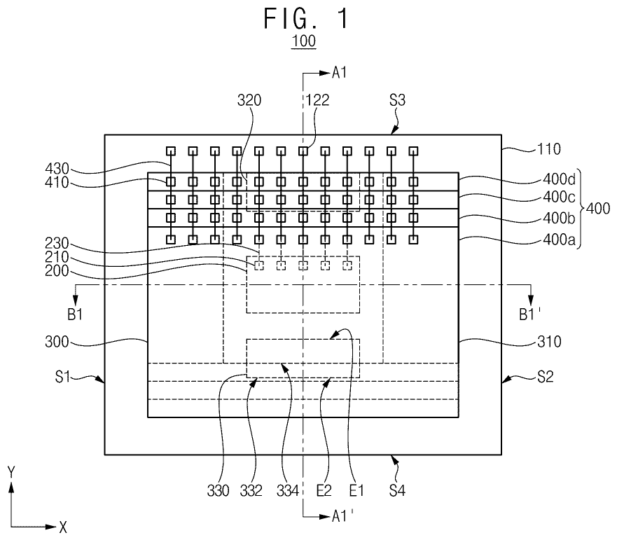

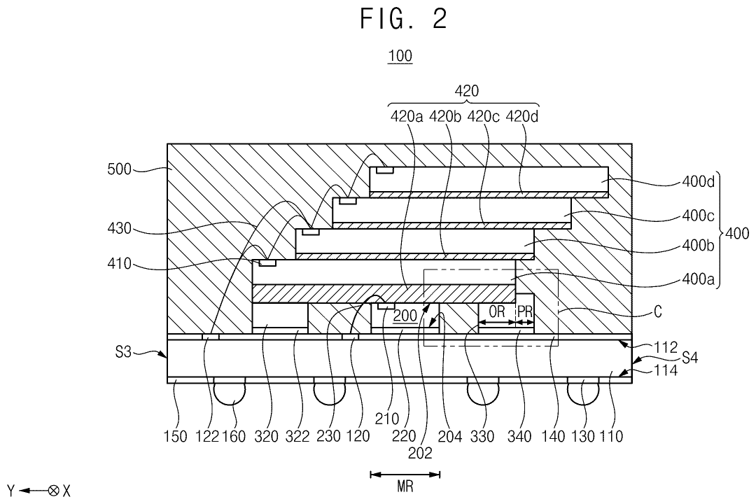

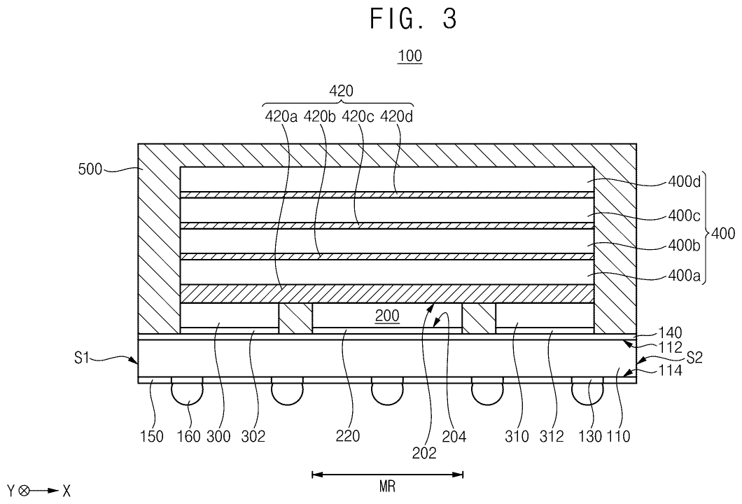

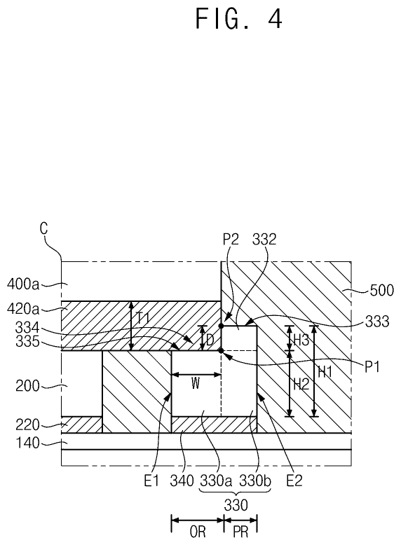

FIG. 1 is a plan view illustrating a semiconductor package in accordance with example embodiments. FIG. 2 is a cross-sectional view taken along the line A1-A1′ in FIG. 1. FIG. 3 is a cross-sectional view taken along the line B1-B1′ in FIG. 1. FIG. 4 is an enlarged cross-sectional view illustrating portion ‘C’ in FIG. 3. FIG. 1 is a plan view illustrating the semiconductor package of FIGS. 2 and 3, wherein a molding member is omitted.

Referring to FIGS. 1 to 4, a semiconductor package 100 may include a package substrate 110, at least one first semiconductor chip 200, at least one spacer chip 330, a plurality of second semiconductor chips 400, and a molding member 500. The semiconductor package 100 may further include conductive connecting members 230 and 430 that electrically connect the first semiconductor chip 200 and the second semiconductor chip 400 to the package substrate 110. In addition, the semiconductor package 100 may further include external connection members 160.

Additionally, the semiconductor package 100 may be a multi-chip package (MCP) such as a universal flash storage (UFS) including different types of semiconductor chips. The semiconductor package 100 may be a System In Package (SIP) including a plurality of semiconductor chips stacked or arranged in one package to perform all or most of the functions of an electronic system.

In example embodiments, the package substrate 110 may be a substrate having an upper surface 112 and a lower surface 114 opposite to the upper surface 112. For example, the package substrate 110 may include a printed circuit board (PCB), a flexible substrate, a tape substrate, etc. The printed circuit board may be a multilayer circuit board having vias and various circuits therein. The package substrate 110 may include internal wires that serve as channels for electrical connection between the first semiconductor chip 200 and the second semiconductor chips 400.

The package substrate 110 may include a first side portion S1 and a second side portion S2 extending in a direction perpendicular to the upper surface 112 and parallel with a second direction (Y direction) and facing each other, and a third side portion S3 and a fourth side portion S4 extending in a direction parallel with a first direction (X direction) perpendicular to the second direction and facing each other.

The package substrate 110 may have a chip mounting region MR in a central region. As will be described below, the chip mounting region MR may be a region where the first semiconductor chip 200 as a controller chip is mounted. The chip mounting region MR may have a rectangular shape.

The package substrate 110 may include first substrate pads 120 arranged adjacent to the chip mounting region MR and second substrate pads 122 arranged along one side portion S2 of the package substrate 110. The first and second substrate pads 120 and 122 may be respectively connected to the wires. The wires may extend in the upper surface 112 of the package substrate 110 or inside the package substrate 110. For example, at least a portion of the wire may be used as the substrate pad as a landing pad.

Although only some substrate pads are illustrated in the figures, the number, shape, and arrangement of the substrate pads are provided as examples, and it will be understood that the present inventive concept is not limited thereto.

A first insulation layer 140 may be formed on the upper surface 112 of the package substrate 110 to expose the first and second substrate pads 120 and 122. The first insulation layer 140 may cover the entire upper surface 112 of the package substrate 110 except for the first and second substrate pads 120 and 122. For example, the first insulation layer may include a solder resist.

In example embodiments, the first semiconductor chip 200 may be mounted on the chip mounting region MR of the package substrate 110. The first semiconductor chip 200 may be mounted on the package substrate 110 by a wire bonding method. The first semiconductor chip 200 may be arranged such that a backside surface 204 opposite to a front surface 202, i.e., an active surface on which first chip pads 210 are formed faces the package substrate 110. When viewed in a plan view, the first semiconductor chip 200 may have a quadrangular shape having four sides. The first chip pads 210 may be arranged to be spaced apart from each other in one side on the front surface 202 of the first semiconductor chip 200.

The first semiconductor chip 200 may be a logic chip including a logic circuit. The logic chip may be a controller that controls memory chips. The first semiconductor chip may be a processor chip such as an ASIC and an application processor AP serving as a host such as CPU, GPU, or SOC.

The first semiconductor chip may be attached to the package substrate 110 by an adhesive film 220. The first chip pads 210 of the first semiconductor chip may be connected to the first substrate pads 120 of the package substrate 110 by conductive connection members, for example, bonding wires.

For example, a thickness of the first semiconductor chip 200 may be within a range of 40 μm to 80 μm. A thickness of the adhesive film 220 may be within the range of 5 μm to 20 μm. A height of the first semiconductor chip 200 from the upper surface 112 of the package substrate 110 may be within a range of 45 μm to 100 μm.

Alternatively, the first semiconductor chip 200 may be mounted on the package substrate 110 by a flip chip bonding method. The first chip pads 210 of the first semiconductor chip 200 may be electrically connected to the first substrate pads 120 of the package substrate 110 by conductive bumps, for example, solder bumps. In this case, the first chip pads 210 may be arranged in an array form over the entire front surface 202 of the first semiconductor chip 200, and the first substrate pads 120 may be arranged within the chip mounting region MR corresponding to the first chip pads.

In example embodiments, first, second, third and fourth spacer chips 300, 310, 320 and 340 may be on the package substrate 110 to extend around or surround the first semiconductor chip 200 on the chip mounting region MR. The first, second, third and fourth spacer chips 300, 310, 320 and 330 may be attached to the upper surface 112 of the package substrate 110 by adhesive films 302, 312, 322 and 340 to be spaced apart from each other.

The first and second spacer chips 300 and 310 may be spaced apart from each other in the first direction (X direction) with the chip mounting area MR interposed between the first and second spacer chips 300 and 310. The third and fourth spacer chips 320 and 330 may be spaced apart from each other in the second direction (Y direction) with the chip mounting region MR interposed between the third and fourth spacer chips 320 and 330. The first spacer chip 300 may be adjacent to the first side portion S1, the second spacer chip 310 may be adjacent to the second side portion S2, the third spacer chip 320 may be adjacent to the third side portion S3, and the fourth spacer chip 330 may be adjacent to the fourth side portion S4.

The height of the first semiconductor chip 200 from the upper surface 112 of the package substrate 110 may be equal to or greater than the heights of upper surfaces of the first, second and third spacer chips 300, 310, 320.

In example embodiments, the plurality of second semiconductor chips 400 may be attached to the first, second, third and fourth spacer chips 300, 310, 320 and 330 using adhesive films 420. A lowermost second semiconductor chip 400a of the plurality of second semiconductor chips may be attached to the first, second, third and fourth spacer chips 300, 310, 320 and 330 using a first adhesive film 420a. The remaining chips 400b, 400c and 400d of the plurality of second semiconductor chips may be sequentially attached on the lowermost second semiconductor chip 400a using second adhesive films 420b, 420c and 420d.

The second semiconductor chip may include a memory chip including a memory circuit. For example, the second semiconductor chip may include a volatile memory device such as an SRAM device, a DRAM device, etc. and a nonvolatile memory device such as a flash memory device, a PRAM device, an MRAM device, an RRAM device, etc.

The lowermost second semiconductor chip 400a may be attached on the first, second, third and fourth spacer chips 300, 310, 320 and 330 and the first semiconductor chip 200 using the first adhesive film 420a such as a die attach film (DAF) by a die attach process.

The second semiconductor chip 400a may be arranged such that a backside surface, i.e., an inactive surface opposite to a front surface on which second chip pads 410 are formed, faces the package substrate 110. When viewed in a plan view, the second semiconductor chip 400a may have a quadrangular shape having four sides.

As illustrated in FIGS. 1 and 2, in example embodiments, the spacer chip 330 may include a first spacer portion 330a provided in a first region OR and a second spacer portion 330b provided in a second region PR. The first region OR may be provided as an overlapping region on which a semiconductor chip is placed, and the second region PR may be provided as an overhang region protruding from one side of the semiconductor chip. The spacer chip 330 may include a first side surface E1 and a second side surface E2 opposite to the first side surface E1. The first side surface E1 and the second side surface E2 may extend in the same direction.

For example, the first adhesive film 420a may be attached to the backside surface of the second semiconductor chip 400a, and the second semiconductor chip 400a to which the first adhesive film 420a is attached may be attached on the first, second, third and fourth spacer chips 300, 310, 320 and 330 and the first semiconductor chip 200 by a thermal compression process. The second semiconductor chip 400a may be pressed onto the first, second, third and fourth spacer chips 300, 310, 320 and 330 by a die attaching tool, and then may be heated to a high temperature by a heater block inside a support system that supports the package substrate 110.

A thickness of the first adhesive film 420a may be within a range of 10 μm to 60 μm. The first adhesive film 420a may be a wire-embedded adhesive film (film over wire, FOW). The first adhesive film 420a may cover the bonding wires 230 having a loop height from the upper surface of the first semiconductor chip 200.

As illustrated in FIG. 4, the fourth spacer chip 330 may include a recess 334 provided in an upper surface 335 of the overlapping region OR. The recess 334 may have a predetermined depth D from an upper surface 333 of the overhang region PR. The recess 334 may have a step shape formed between the first side surface E1 and the upper surface 333 of the overhang region PR. The recess 334 may extend in the extension direction of the first side surface E1.

The fourth spacer chip 330 may include a dam structure 332 provided on the upper surface of the overhang region PR. The dam structure 332 may have a predetermined height H3 from the upper surface 335 of the overlapping region OR. The recess 334 may be defined by the dam structure 332. The depth D of the recess 334 may be the same as the height H3 of the dam structure 332. The spacer chip 330 may have a first height H1. The first spacer portion 330a may have a second height H2, and the second spacer portion 330b may have the first height H1. For example, the first height H1, i.e., a thickness of the fourth spacer chip 330 may be within a range of 50 μm to 250 μm. The depth of the recess may be within the range of 5 μm to 70 μm. The length of one side of the fourth spacer chip 330 in the first direction may be within a range of 2 mm to 8 mm.

A portion of the first adhesive film 420a attached to the fourth spacer chip 330 may be provided to fill the recess 334 of the fourth spacer chip 330. The depth D of the recess 334 may be equal to or smaller than the thickness T1 of the first adhesive film 420a. A lower edge portion P1 of the first adhesive film 420a attached to the fourth spacer chip 330 may be in contact with a bottom surface of the recess 334. A height H3 of the dam structure 332 may be smaller than the thickness T1 of the first adhesive film 420a. The dam structure 332 of the fourth spacer chip 330 may cover a lower side surface of the first adhesive film 420a attached to the fourth spacer chip 330. The lower edge portion P1 of the first adhesive film 420a on the overlapping area OR of the fourth spacer chip 330 may be covered by the dam structure 332. A central side portion P2 of the first adhesive film 420a attached to the fourth spacer chip 330 may be exposed to the outside. Accordingly, an area of the side surface of the first adhesive film 420a attached to the fourth spacer chip 330 exposed to the outside by the dam structure 332 may be reduced. The lower edge portion P1 of the first adhesive film 420a on the overlapping region OR may be covered by the dam structure 332 to reduce or prevent contact with the sealing member 500.

The remaining chips 400b, 400c and 400d of the plurality of second semiconductor chips may be sequentially attached to the lowermost second semiconductor chip 400a by second adhesive films 420b, 420c and 420d. The second semiconductor chips 400b, 400c and 400d be sequentially attached to the lowermost second semiconductor chip 400a using the second adhesive film 420b, 420c and 420d such as a die attach film (DAF) by a die attach process. Thicknesses of the second adhesive films 420b, 420c and 420d may be within a range of 10 μm to 20 μm.

A planar area of the second semiconductor chip may be greater than a planar area of the first semiconductor chip. Accordingly, the second semiconductor chips 400a, 400b, 400c and 400d may be supported and mounted on the package substrate 110 by the first, second, third and fourth spacer chips 300, 310, 320 and 330.

The plurality of second semiconductor chips 400a, 400b, 400c and 400d may be sequentially offset aligned. For example, the second semiconductor chips 400a, 400b, 400c, and 400d may be stacked in a cascade structure. The second semiconductor chips 400a, 400b, 400c and 400d may be sequentially offset aligned in a first lateral direction (−X direction) of the package substrate 110.

The number, sizes, arrangements, etc. of the second semiconductor chips are provided as examples, and it will be understood that the present inventive concept is not limited thereto. Additionally, although only a few second chip pads are illustrated in the figures, the structures, shapes, and arrangements of the second chip pads are provided as examples, and it will be understood that the present inventive concept is not limited thereto.

In example embodiments, the second semiconductor chips 400 may be electrically connected to the package substrate 110 by conductive connecting members 430.

In particular, the second chip pads 410 of the second semiconductor chips 400 may be connected to the second substrate pads 122 on the upper surface 112 of the package substrate 110 by bonding wires 430.

In example embodiments, the molding member 500 may cover the first, second, third and fourth spacer chips 300, 310, 320 and 330, the second semiconductor chips 400 and the bonding wires 430 on the upper surface 112 of the package substrate 110. The molding member may include a thermosetting resin, for example, epoxy molding compound (EMC).

In example embodiments, external connection pads 130 for providing electrical signals may be formed on the lower surface 114 of the package substrate 110. The external connection pads 130 may be exposed by a second insulating layer 150. The second insulating layer may include a silicon oxide layer, a silicon nitride layer, or a silicon oxynitride layer. An external connection member 160 may be on the external connection pad 130 of the package substrate 110 for electrical connection with an external device. For example, the external connection member 160 may be a solder ball. The semiconductor package 100 may be mounted on a module substrate via the solder balls to provide a memory module.

As mentioned above, the semiconductor package 100 may include the first, second, third and fourth spacer chips 300, 310, 320, and 330 that are spaced apart from each other on the package substrate 110 with the first semiconductor chip 200 interposed therebetween, the plurality of second semiconductor chips 400 attached to the first, second, third and fourth spacer chips 300, 310, 320 and 330 by the adhesive films 420 so as to cover the first semiconductor chip 200 and electrically connected to the package substrate 110 by the plurality of bonding wires 430, and the molding member 500 covering the second semiconductor chips 400 on the package substrate 110.

The lowermost second semiconductor chip 400a to which the first adhesive film 420a is attached may be attached to the first, second, third and fourth spacer chips 300, 310, 320, 330 and the first semiconductor chip 200 by a thermal compression process. At least a portion of the fourth spacer chip 330, that is, the overlapping region may be arranged to overlap with the lowermost second semiconductor chip 400a, and the recess 334 may be provided in the upper surface of the overlapping region OR of the fourth spacer chip 330 that overlaps with the lowermost second semiconductor chip 400a.

The lower edge portion P1 of the first adhesive film 420a attached to the fourth spacer chip 330 may be in contact with the bottom surface of the recess 334. The lower edge portion P1 of the first adhesive film 420a on the overlapping area OR of the fourth spacer chip 330 may be covered by the dam structure 332. The central side portion P2 of the first adhesive film 420a attached to the fourth spacer chip 330 may be in contact with the molding member 500. Accordingly, a triple point where three different materials (spacer chip, adhesive film, and molding member) meet moves to the central side portion P2 of the first adhesive film 420a, to thereby reduce or prevent the occurrence of interface peeling of the first adhesive film 420a in the overhang region OR of the fourth spacer chip 330.

An area of the side surface of the first adhesive film 420a attached to the fourth spacer chip 330 that comes into contact with the molding member 500 may be reduced by the dam structure 332. Accordingly, in a high-humidity test process, the reliability of the adhesive film having a relatively large moisture absorption expansion amount compared to EMC may be improved.

Hereinafter, a method of manufacturing the semiconductor package of FIG. 1 will be described.

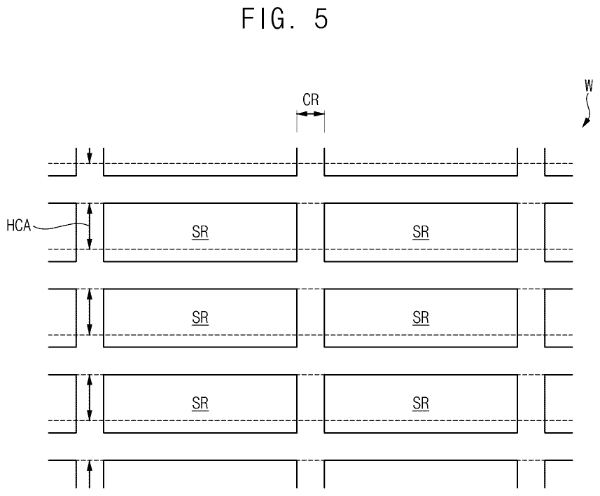

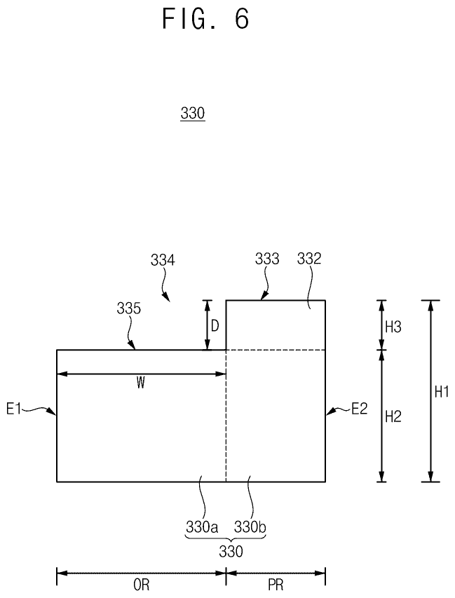

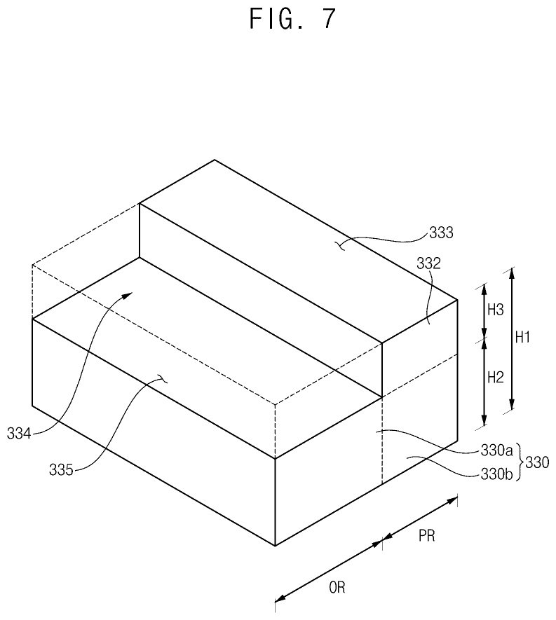

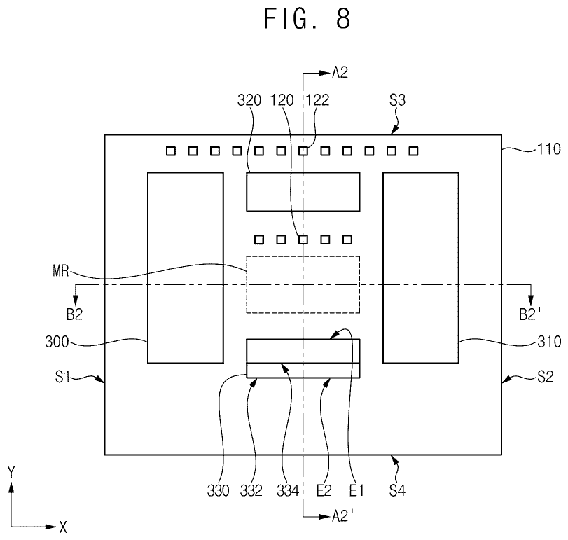

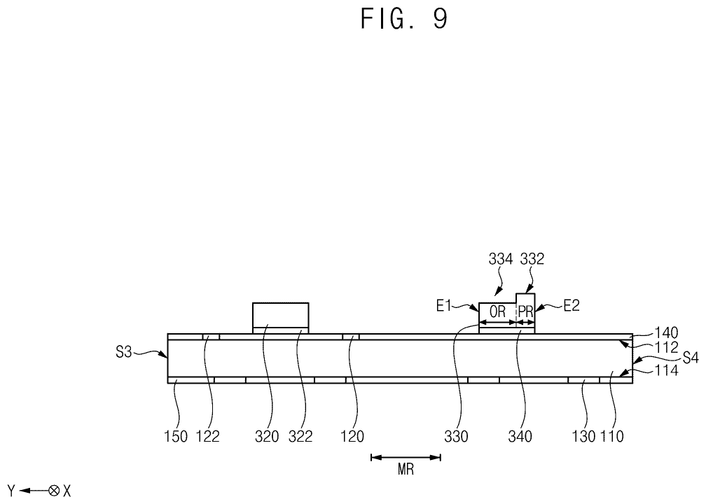

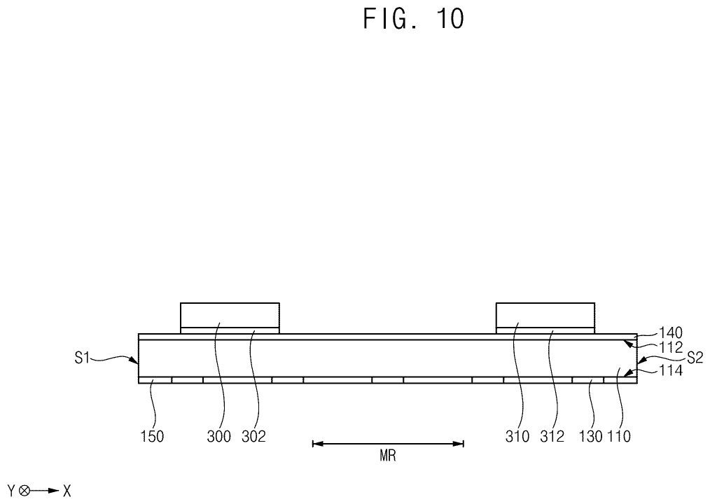

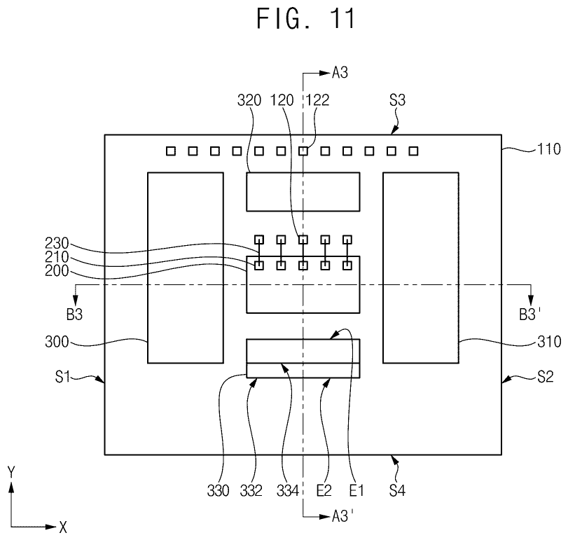

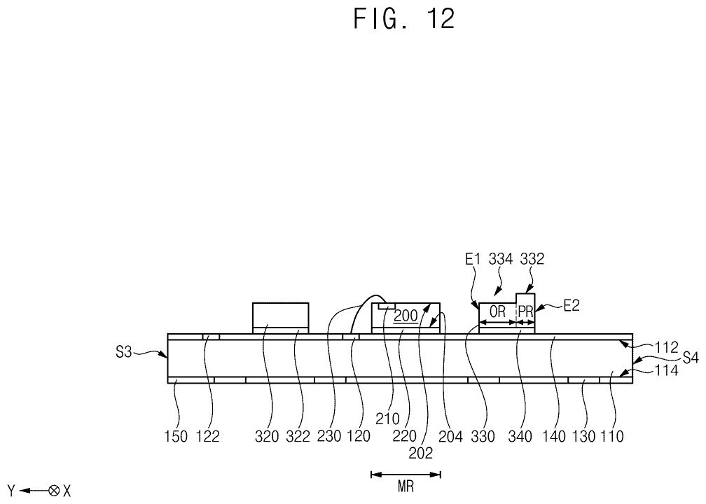

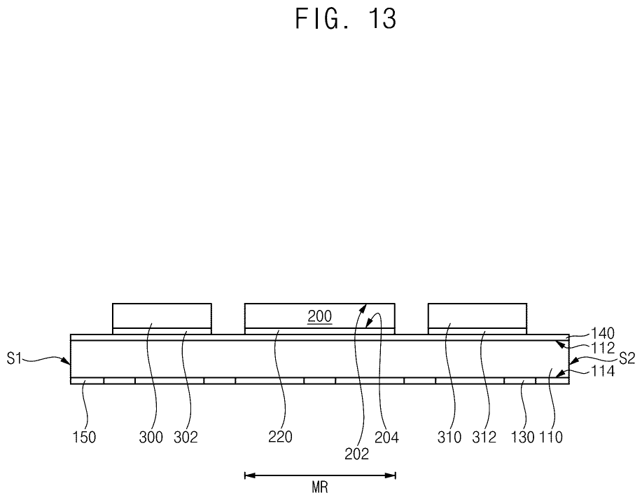

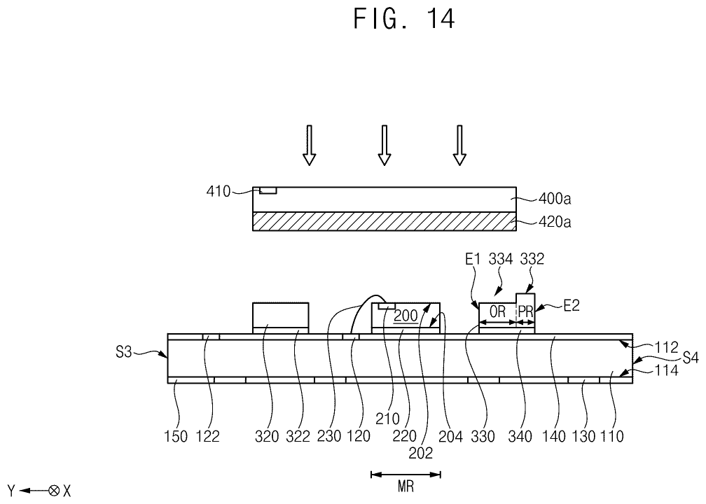

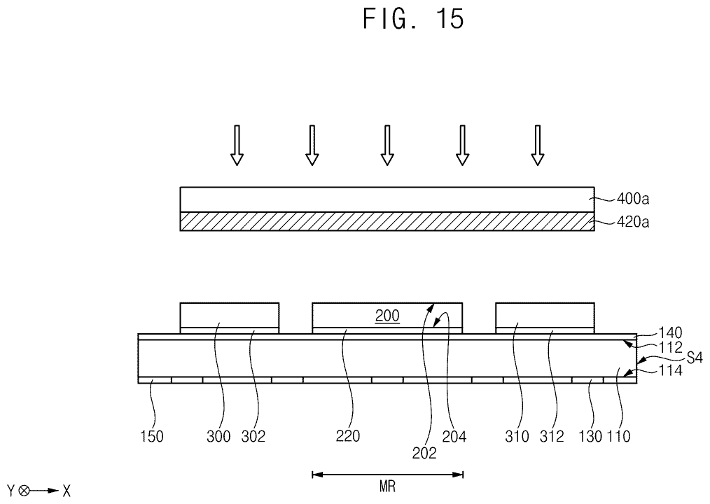

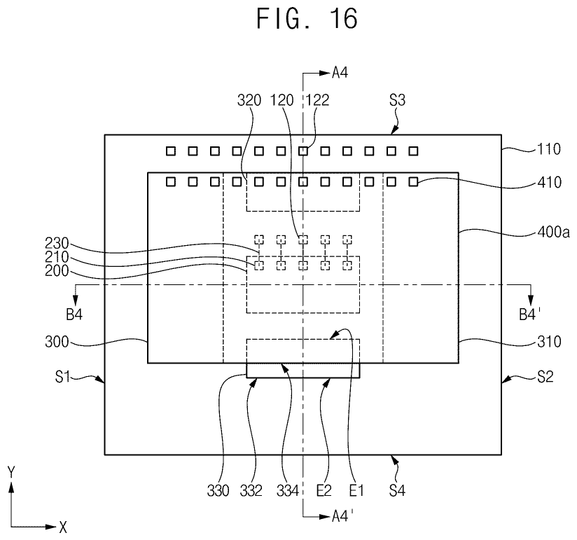

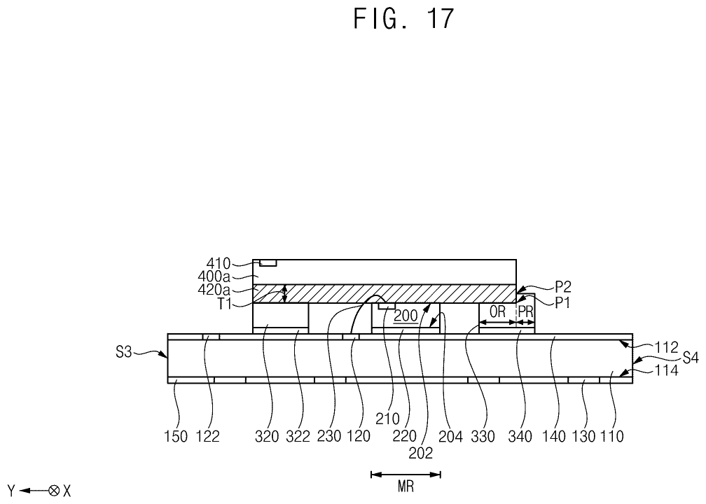

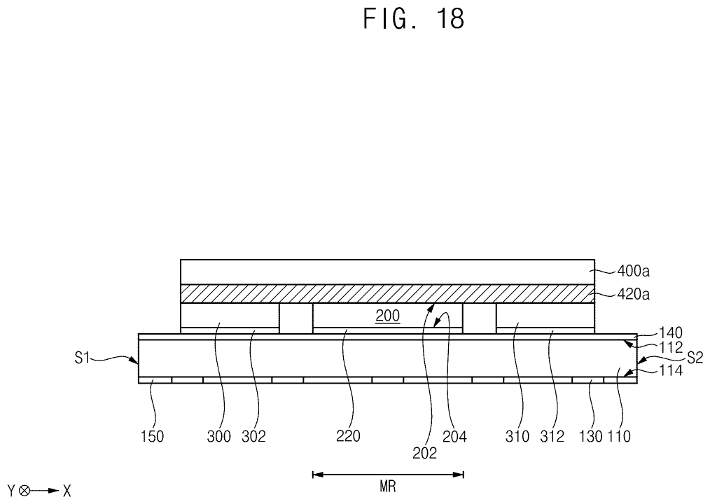

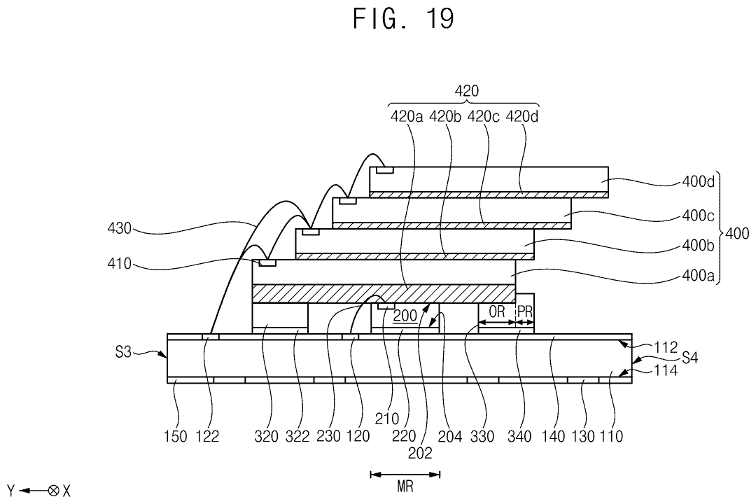

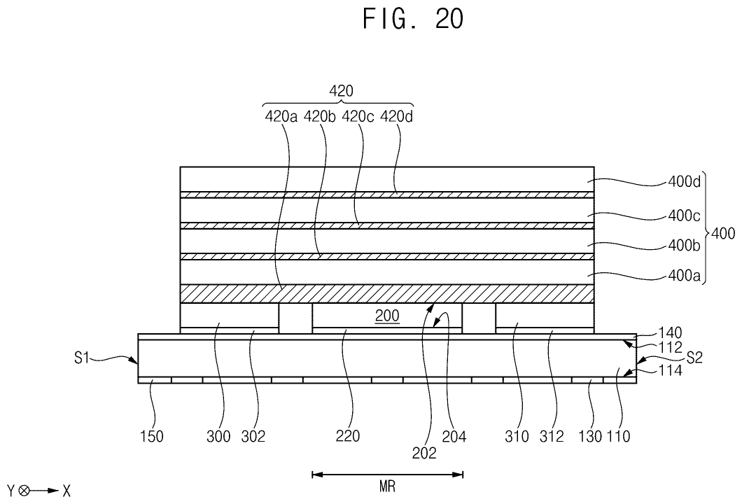

FIGS. 5 to 20 are views illustrating a method of manufacturing a semiconductor package in accordance with example embodiments. FIG. 5 is a plan view illustrating a portion of a wafer including spacer chips formed therein. FIG. 6 is a cross-sectional view illustrating a spacer chip formed by a sawing process. FIG. 7 is a perspective view illustrating the space chip in FIG. 6. FIGS. 10, 11 and 16 are plan views illustrating a method of manufacturing a semiconductor package in accordance with example embodiments. FIG. 9 is a cross-sectional view taken along the line A2-A2′ in FIG. 8. FIG. 10 is a cross-sectional view taken along the line B2-B2′ in FIG. 8. FIGS. 12 and 14 are cross-sectional views taken along the line A3-A3′ in FIG. 11. FIGS. 13 and 15 are cross-sectional views taken along the line B3-B3′ in FIG. 11. FIGS. 17 and 19 are cross-sectional views taken along the line A4-A4′ in FIG. 16. FIGS. 18 and 20 are cross-sectional views taken along the line B4-B4′ in FIG. 16.

Referring to FIGS. 5 to 7, individual spacer chips 330 may be formed by cutting a wafer W through a sawing process.

As illustrated in FIG. 5, after a backside surface of the silicon wafer W is partially removed by a polishing process so that the wafer has a desired thickness, the silicon wafer W may be mounted on an adhesive tape sheet (not illustrated) (Wafer Mounting).

In example embodiments, the wafer W may include spacer chip regions SR and a cutting region CR defining the spacer chip regions SR. A recess region HCA may be provided in the spacer chip region SR. The wafer may include, for example, silicon, germanium, silicon-germanium, or III-V compound compounds, e.g., GaP, GaAs, GaSb, etc. The wafer may be polished to have a thickness of, for example, 50 μm to 250 μm.

After attaching the adhesive tape sheet on a ring frame (not illustrated), the wafer W may be attached on the adhesive tape sheet. For example, the ring frame may have an annular shape. The adhesive tape sheet may be a dicing adhesive tape having a circular shape.

Then, a recess may be formed in the recess region HCA of the silicon wafer W, and the wafer W may be cut by a sawing process to form individual spacer chips 330.

First, an upper surface of the recess region HCA may be partially removed to form a preliminary recess. The preliminary recess may include a trench that extends in a first direction in the upper surface of the wafer W. The preliminary recess may have a predetermined width and depth. The width and the depth of the preliminary recess may be determined in consideration of a size of a portion where an adhesive film is received, as described below.

The preliminary recess may be formed by an etching process. The preliminary recess may be formed by partially removing the upper surface of the recess region HCA using a blade. Sidewalls of the preliminary recess may extend in a thickness direction or an inclined direction with respect to the upper surface of the wafer.

Then, the cutting region CR may be removed to form the individual spacer chips 330 of FIG. 6. Then, the adhesive tape sheet may be expanded in a radial direction by a tape expanding apparatus, so that the divided spacer chips 330 on the adhesive tape sheet may be spaced apart from each other in the radial direction.

As illustrated in FIGS. 6 and 7, the spacer chip 330 may include a first spacer portion 330a provided in a first region OR and a second spacer portion 330b provided in a second region PR. The first region OR may be provided as an overlapping region on which a semiconductor chip is placed, and the second region PR may be provided as an overhang region protruding or extending from one side of the semiconductor chip. The spacer chip 330 may include a first side surface E1 and a second side surface E2 opposite to the first side surface E1. The first side surface E1 and the second side surface E2 may extend in the same direction.

The spacer chip 330 may include a recess 334 provided in an upper surface 335 of the overlapping region OR. The recess 334 may have a predetermined depth D from an upper surface 333 of the overhang region PR. When the cutting region CR of the wafer W is removed, a portion of the preliminary recess may be removed together to form the recess 334. The recess 334 may have a step shape formed between the first side surface E1 and the upper surface 333 of the overhang region PR. The recess 334 may extend in the extension direction of the first side surface E1.

The spacer chip 330 may include a dam structure 332 provided on the upper surface of the overhang region PR. The dam structure 332 may have a predetermined height H3 from the upper surface 335 of the overlapping region OR. The recess 334 may be defined by the dam structure 332. The depth D of the recess 334 may be the same as the height H3 of the dam structure 332. The spacer chip 330 may have a first height H1. The first spacer portion 330a may have a second height H2, and the second spacer portion 330b may have the first height H1. For example, the first height H1, i.e., a thickness of the spacer chip 330 may be within a range of 50 μm to 250 μm. The depth of the recess may be within the range of 5 μm to 70 μm. The length of one side of the spacer chip 330 in the first direction may be within a range of 2 mm to 8 mm. As described below, the spacer chip 330 including the recess 334 formed therein may be provided as a fourth spacer chip.

Referring to FIGS. 8 to 10, at least one spacer chip may be on a package substrate 110. The at least one spacer chip may include the spacer chip 330 of FIG. 6 including the recess 334 formed therein.

In example embodiments, the package substrate 110 may be a substrate having an upper surface 112 and a lower surface 114 opposite to the upper surface 112. For example, the package substrate 110 may be a printed circuit board (PCB). The printed circuit board may be a multilayer circuit board having vias and various circuits therein. The package substrate 110 may include internal wires serving as channels for electrical connection between first and second semiconductor chips as will be described below.

The package substrate 110 may a first side portion S1 and a second side portion S2 extending in a direction perpendicular to the upper surface 112 and parallel with a second direction (Y direction) and facing each other, and a third side portion S3 and a fourth side portion S4 extending in a direction parallel with the first direction (X direction) and facing each other.

The package substrate 110 may have a chip mounting region MR in a central region. As will be described below, the chip mounting region MR may be a region where a first semiconductor chip as a controller chip is mounted. The chip mounting region MR may have a rectangular shape.

For example, a width of the package substrate 110 in the first direction (X direction) may range from 10 mm to 15 mm, and a width of the package substrate 110 in the second direction (Y direction) may range from 4 mm to 7 mm. A side of the chip mounting region MR may have a length within a range of 2 mm to 4 mm.

The package substrate 110 may include first substrate pads 120 adjacent to the chip mounting region MR and second substrate pads 122 arranged along one side portion S3 of the package substrate 110. The first and second substrate pads 120 and 122 may be respectively connected to the wires. The wires may extend from the upper surface 112 of the package substrate 110 or inside the of the package substrate 110. For example, at least a portion of the wire may be used as the substrate pad as a landing pad.

Although only some substrate pads are illustrated in the figures, the number, shape, and arrangement of the substrate pads are provided as examples, and it will be understood that the present inventive concept is not limited thereto.

A first insulating layer 140 may be formed on the upper surface 112 of the package substrate 110 to expose the first and second substrate pads 120 and 122. The first insulating layer 140 may cover the entire upper surface 112 of the package substrate 110 except for the first and second substrate pads 120 and 122. For example, the first insulating layer may include a solder resist.

In example embodiments, first, second, third and fourth spacer chips 300, 310, 320 and 330 may be on the package substrate 110 to extend around or surround the chip mounting region MR. The first, second, third and fourth spacer chips 300, 310, 320 and 330 may be attached to the upper surface 112 of the package substrate 110 by using adhesive films 302, 312, 322 and 340 to be spaced apart from each other.

The first and second spacer chips 300 and 310 may be spaced apart from each other in the first direction (X direction) with the chip mounting region MR interposed therebetween. The third and fourth spacer chips 320 and 330 may be spaced apart from each other in the second direction (Y direction) with the chip mounting region MR interposed therebetween. The first, second, third and fourth spacer chips 300, 310, 320, and 330 may be formed by cutting the silicon wafer W through a sawing process, and then, may be attached on the upper surface 112 of the package substrate 110 using the adhesive films 302, 312, 322 and 340 by a die attach process. The recess 334 may be formed in the upper surface of the fourth spacer chip 330.

Each of the first to third spacer chips 300, 310, 320 may have a flat upper surface. The recess 334 may be formed in the upper surface of the fourth spacer chip 330. Heights of the first to third spacer chips 300, 310, 320 from the package substrate 110 may be the same. A height of the fourth spacer chip 330 from the package substrate 110 may be greater than the heights of the first to third spacer chips 300, 310, 320.

Referring to FIGS. 11 to 13, a first semiconductor chip 200 may be mounted on the package substrate 110.

In example embodiments, the first semiconductor chip 200 may be mounted on the package substrate 110 by an adhesive film 220. The first semiconductor chip 200 may be arranged such that a backside surface 204 of a front surface 202, i.e., an active surface on which first chip pads 210 are formed faces the package substrate 110. When viewed in a plan view, the first semiconductor chip 200 may have a quadrangular shape having four sides. The first chip pads 210 may be arranged to be spaced apart from each other in one side on the front surface 202 of the first semiconductor chip 200.

The first semiconductor chip 200 may be a logic chip including a logic circuit. The logic chip may be a controller that controls memory chips. The first semiconductor chip may be a processor chip such as an ASIC or an application processor AP serving as a host such as a CPU, GPU, or SOC.

The first semiconductor chip 200 may be mounted on the package substrate 110 by a wire bonding method. After the first semiconductor chip 200 is attached on the upper surface 112 of the package substrate 110 using the adhesive film 220, a wire bonding process may be performed to connect the first chip pads 210 of the first semiconductor chip 200 to the first substrate pads 120 on the upper surface 112 of the package substrate 110. The first chip pads 210 of the first semiconductor chip 200 may be connected to the first substrate pads 120 by bonding wires 230 as conductive connecting members.

For example, a thickness of the first semiconductor chip 200 may be within a range of 40 μm to 80 μm. A thickness of the adhesive film 220 may be within the range of 5 μm to 20 μm. A height of the first semiconductor chip 200 from the upper surface 112 of the package substrate 110 may be within a range of 45 μm to 100 μm. The height of the first semiconductor chip 200 from the upper surface 112 of the package substrate 110 may be equal to or greater than the heights of upper surfaces of the first, second and third spacer chips 300, 310, 320.

Alternatively, the first semiconductor chip 200 may be mounted on the package substrate 110 by a flip chip bonding method. The first chip pads 210 of the first semiconductor chip 200 may be electrically connected to the first substrate pads 120 of the package substrate 110 by conductive bumps, for example, solder bumps. In this case, the first chip pads 210 may be arranged in an array form over the entire front surface 202 of the first semiconductor chip 200, and the first substrate pads 120 may be arranged within the chip mounting region MR corresponding to the first chip pads.

Referring to FIGS. 14 to 20, a plurality of second semiconductor chips 400 may be attached on the first, second, third and fourth spacer chips 300, 310, 320 and 330 using adhesive films 420.

As illustrated in FIGS. 14 to 18, a lowermost second semiconductor chip 400a may be attached onto the first, second, third and fourth spacer chips 300, 310, 320 and 330 using a first adhesive film 420a. The lowermost second semiconductor chip 400a may be attached to the first, second, third and fourth spacer chips 300, 310, 320 and 330 and the first semiconductor chip 200 using the first adhesive film 420a such as a die attach film (DAF) by a die attach process.

The second semiconductor chip 300a may be positioned such that a backside surface, i.e., a non-active surface opposite to a front surface on which second chip pads 410 are formed, faces the package substrate 110. When viewed in a plan view, the second semiconductor chip 400a may have a quadrangular shape having four sides.

The second semiconductor chip may include a memory chip including a memory circuit. For example, the second semiconductor chip may include a volatile memory device such as an SRAM device and a DRAM device, and a non-volatile memory device such as a flash memory device, a PRAM device, an MRAM device and an RRAM device.

In example embodiments, at least a portion of the fourth spacer chip 330, that is, the overlapping region may be arranged to overlap with the lowermost second semiconductor chip 400a. The recess 334 may be provided in the upper surface of the overlapping region OR of the fourth spacer chip 330 that overlaps with the lowermost second semiconductor chip 400a. The overhang region PR of the fourth spacer chip 330 may be arranged to protrude or extend from one side of the lowermost second semiconductor chip 400a. The dam structure 332 may be provided in the upper surface of the overhang region PR of the fourth spacer chip 330 that protrudes or extends away from one side of the lowermost second semiconductor chip 400a.

For example, the first adhesive film 420a may be attached to the backside surface of the second semiconductor chip 400a, and the second semiconductor chip 400a to which the first adhesive film 420a is attached may be attached on the first, second, third and fourth spacer chips 300, 310, 320 and 330 and the first semiconductor chip 200 by a thermal compression process. The second semiconductor chip 400a may be pressed onto the first, second, third and fourth spacer chips 300, 310, 320, and 330 by a die attaching tool, and may be heated to a high temperature by a heater block inside a support system that supports the package substrate 110.

A thickness of the first adhesive film 420a may be within a range of 10 μm to 60 μm. The first adhesive film 420a may be a wire-embedded adhesive film (film over wire, FOW). The first adhesive film 420a may cover the bonding wires 230 having a loop height from the upper surface of the first semiconductor chip 200.

As illustrated in FIG. 17, a portion of the first adhesive film 420a attached to the fourth spacer chip 330 may be formed to fill the recess 334 of the fourth spacer chip 330. The depth D of the recess 334 may be equal to or smaller than the thickness T1 of the first adhesive film 420a. A lower edge portion P1 of the first adhesive film 420a attached to the fourth spacer chip 330 may be in contact with a bottom surface of the recess 334. A height H3 of the dam structure 332 may be smaller than the thickness T1 of the first adhesive film 420a. The dam structure 332 of the fourth spacer chip 330 may cover a lower side surface of the first adhesive film 420a attached to the fourth spacer chip 330. The lower edge portion P1 of the first adhesive film 420a on the overlapping area OR of the fourth spacer chip 330 may be covered by the dam structure 332. A central side portion P2 of the first adhesive film 420a attached to the fourth spacer chip 330 may be exposed to the outside. Accordingly, an area of the side surface of the first adhesive film 420a attached to the fourth spacer chip 330 exposed to the outside by the dam structure 332 may be reduced.

Then, as illustrated in FIGS. 19 and 20, the remaining chips 400b, 400c and 400d of the plurality of second semiconductor chips may be sequentially attached to the lowermost second semiconductor chip 400a using second adhesive films 420b, 420c and 420d. The second semiconductor chips 400b, 400c and 400d may be sequentially attached on the lowermost second semiconductor chip 400a using second adhesive films 420b, 420c and 420d such as a die attach film (DAF) by a die attach process. A thickness of each of the second adhesive films 420b, 420c and 420d may be within a range of 10 μm to 20 μm.

A planar area of the second semiconductor chip may be greater than a planar area of the first semiconductor chip. Accordingly, the second semiconductor chips 400a, 400b, 400c and 400d may be supported and mounted on the package substrate 110 by the first, second, third and fourth spacer chips 300, 310, 320 and 330.

The plurality of second semiconductor chips 400a, 400b, 400c and 400d may be sequentially offset aligned. For example, the second semiconductor chips 400a, 400b, 400c, and 400d may be stacked in a cascade structure. The second semiconductor chips 400a, 400b, 400c and 400d may be sequentially offset aligned in a first lateral direction (−X direction) of the package substrate 110.

The number, sizes, arrangements, etc. of the second semiconductor chips are provided as examples, and it will be understood that the present inventive concept is not limited thereto. Additionally, although only a few second chip pads are illustrated in the figures, the structures, shapes, and arrangements of the second chip pads are provided as examples, and it will be understood that the present inventive concept is not limited thereto.

Then, the second semiconductor chips 400 may be electrically connected to the package substrate 110 by conductive connecting members 430.

In example embodiments, a wire bonding process may be performed to connect the second chip pads 410 of the second semiconductor chips 400 to the second substrate pads 122 on the upper surface 112 of the package substrate 110 by bonding wires 430.

Then, a molding member (500, see FIG. 2) may be formed on the upper surface 112 of the package substrate 110 to cover the first, second, third and fourth spacer chips 300, 310, 320 and 330, the second semiconductor chips 400 and the bonding wires 430. The molding member may include a thermosetting resin, for example, epoxy molding compound (EMC).

The central side portion P2 of the first adhesive film 420a on the overlapping region OR of the fourth spacer chip 330 rather than the lower edge portion P1 may be exposed and may come into contact with the molding member 500. Accordingly, a triple point where three different materials (spacer chip, adhesive film, and molding member) meet moves to the central side portion P2 of the first adhesive film 420a, to thereby reduce or prevent the occurrence of interface peeling of the first adhesive film 420a in the overhang region OR of the fourth spacer chip 330.

Then, external connection members (160, see FIG. 2) may be formed on external connection pads 130 on the lower surface 114 of the package substrate 110 to complete the semiconductor package 100 of FIG. 1.

For example, the external connection members may include solder balls. The external connection members may be respectively formed on the external connection pads 130 of the lower surface 114 of the package substrate 110 by a solder ball attach process.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate;
a first semiconductor chip on an upper surface of the package substrate;
a spacer chip on the upper surface of the package substrate, the spacer chip being spaced apart from the first semiconductor chip;
a plurality of second semiconductor chips sequentially stacked on the spacer chip by a plurality of adhesive films, respectively, to cover the first semiconductor chip; and
a molding member on the package substrate and on the spacer chip, the first semiconductor chip, and the plurality of second semiconductor chips,
wherein the spacer chip has an overlapping region that overlaps a lowermost second semiconductor chip of the plurality of second semiconductor chips and an overhang region that extends from one side of the lowermost second semiconductor chip in a plan view,
wherein a recess having a predetermined depth is in an upper surface of the overlapping region of the spacer chip,
wherein the lowermost second semiconductor chip is attached to the spacer chip by a first adhesive film from the plurality of adhesive films, and
wherein a portion of the first adhesive film attached to the spacer chip is within the recess of the spacer chip.

2. The semiconductor package of claim 1, wherein the portion of the first adhesive film fills the recess of the spacer chip.

3. The semiconductor package of claim 1, wherein the recess has a step shape between an inner surface and an upper surface of the spacer chip, the inner surface facing the first semiconductor chip.

4. The semiconductor package of claim 3, wherein the recess extends along the inner surface of the spacer chip.

5. The semiconductor package of claim 4, wherein the depth of the recess is less than a thickness of the first adhesive film.

6. The semiconductor package of claim 1, wherein the depth of the recess is within a range of 5 μm to 70 μm.

7. The semiconductor package of claim 1, wherein the spacer chip has a thickness of 50 μm to 250 μm.

8. The semiconductor package of claim 1, wherein the spacer chip comprises a first spacer chip, and the semiconductor package further comprises:
at least one second spacer chip on the upper surface of the package substrate, the at least one second spacer chip being spaced apart from the first spacer chip in a first direction or a second direction perpendicular to the first direction with the first semiconductor chip therebetween.

9. The semiconductor package of claim 8, wherein the plurality of second semiconductor chips are sequentially offset aligned in the first direction on the first spacer chip and the at least one second spacer chip.

10. The semiconductor package of claim 1, wherein the plurality of adhesive films include a die attach film.

11. A semiconductor package, comprising:
a package substrate;
a first semiconductor chip on an upper surface of the package substrate;
a spacer chip on the upper surface of the package substrate, the spacer chip being spaced apart from the first semiconductor chip in a first direction;
a plurality of second semiconductor chips sequentially stacked on the spacer chip by a plurality of adhesive films, respectively, to cover the first semiconductor chip; and
a molding member on the package substrate and on the spacer chip, the first semiconductor chip and the plurality of second semiconductor chips,
wherein the spacer chip has an overhang region extending from one side of a lowermost second semiconductor chip of the plurality of second semiconductor chips,
wherein a dam structure having a predetermined height is on an upper surface of the overhang region of the spacer chip,
wherein the lowermost second semiconductor chip is attached to the spacer chip by a first adhesive film of the plurality of adhesive films, and
wherein a lower edge portion of the first adhesive film attached to the spacer chip is covered by the dam structure.

12. The semiconductor package of claim 11, wherein remaining chips of the plurality of second semiconductor chips are sequentially attached to the lowermost second semiconductor chip by second adhesive films of the plurality of adhesive films.

13. The semiconductor package of claim 11, wherein the dam structure extends along an outer surface of the spacer chip opposite an inner surface, the inner surface facing the first semiconductor chip.

14. The semiconductor package of claim 11, wherein a height of the dam structure is less than a thickness of the first adhesive film.

15. The semiconductor package of claim 14, wherein the height of the dam structure is within a range of 5 μm to 70 μm.

16. The semiconductor package of claim 11, wherein the spacer chip has a thickness of 50 μm to 250 μm.

17. The semiconductor package of claim 11, wherein the spacer chip includes a silicon material.

18. The semiconductor package of claim 11, wherein the spacer chip comprises a first spacer chip, and the semiconductor package further comprises:
at least one second spacer chip on the upper surface of the package substrate, the at least one second spacer chip being spaced apart from the first spacer chip in the first direction or a second direction perpendicular to the first direction with the first semiconductor chip therebetween.

19. The semiconductor package of claim 11, wherein the plurality of adhesive films include a die attach film.

20. A semiconductor package, comprising:
a package substrate extending in a first direction, and having a plurality of substrate pads formed on an upper surface thereof;
a first semiconductor chip on the upper surface of the package substrate;
first and second spacer chips on the upper surface of the package substrate, the first and second spacer chips being spaced apart from each other in the first direction with the first semiconductor chip between the first and second spacer chips;
third and fourth spacer chips on the upper surface of the package substrate, the third and fourth spacer chips being spaced apart from each other in a second direction perpendicular to the first direction with the first semiconductor chip interposed between the third and fourth spacer chips;
a plurality of second semiconductor chips sequentially stacked on the first, second, third and fourth spacer chips by a plurality of adhesive films, respectively, to cover the first semiconductor chip;
conductive connecting members electrically connecting chip pads of the plurality of second semiconductor chips to the substrate pads, respectively; and
a molding member on the package substrate and on the first, second, third and fourth spacer chips, the first semiconductor chip, and the plurality of second semiconductor chips,
wherein the fourth spacer chip has an overlapping region overlapping with a lowermost second semiconductor chip of the plurality of second semiconductor chips and an overhang region extending from one side of the lowermost second semiconductor chip in a plan view,
wherein a recess having a predetermined depth is in an upper surface of the overlapping region of the fourth spacer chip,
wherein the lowermost second semiconductor chip is attached to the fourth spacer chip by a first adhesive film of the plurality adhesive films, and
wherein a portion of the first adhesive film attached to the fourth spacer chip is within the recess of the fourth spacer chip.
